(19) United States
(12) Patent Application Publication
(10) Pub. No.: US 2008/0050915 A1
(43) Pub. Date: Feb. 28, 2008

(54) Method for manufacturing semiconductor device

(76) Inventor: Satoshi Funase, Niigata (JP)

Correspondence Address: MCDERMOTT WILL & EMERY LLP, 600 13TH STREET, NW, WASHINGTON, DC, 20005-3096, US

(21) Appl. No.: 11/882,663

(22) Filed: Aug. 3, 2007

(30) Foreign Application Priority Data
Aug. 25, 2006 (JP) 2006-229237

(51) Int. Cl. H01L 21/44

(52) U.S. Cl. 438/683; 257/E21.476

(57) ABSTRACT

In the method for manufacturing a semiconductor device relating to the present invention, first, a metal film is formed onto a substrate in the state where a silicide forming region is exposed onto the surface of substrate. Next, thermal processes at pressure higher than atmosphere are conducted to the substrate where the metal film is formed, and a silicide film is formed by reacting silicon contained in the silicide forming region with the metal film. Subsequently, after an unreacted metal film is removed during the thermal process, crystalline phase transition is initiated via the thermal process, and low resistance of the silicide film formed on the substrate is realized. These steps enable the stable formation of the silicide film with low resistance.

### CROSS-REFERENCE TO RELATED APPLICATION

The present application claims the benefit of patent application number 2006-229237, filed in Japan on Aug. 25, 2006, the subject matter of which is incorporated herein by reference.

### BACKGROUND OF THE INVENTION

1. Field of the Invention

The present invention relates to a method for manufacturing a semiconductor device, and to a method for manufacturing a semiconductor device including a silicide film.

2. Description of the Related Art

Associated with recent miniaturization of semiconductor devices, increase of sheet resistance in impurity regions function as a source region and a drain region in a transistor and signal delay caused by the rise of wiring resistance of a gate electrode have become obvious. As counter-acting measures, technology where formation of a silicide film on an impurity region and a gate electrode results in the realization of low resistance in the impurity region and the gate electrode is widely disseminated.

The silicide film is formed by a thermal process after a metal film is deposited onto a semiconductor substrate where an upper surface of the impurity region and an upper surface of the gate electrode made from polysilicon are exposed. As the metal film, titanium, cobalt or nickel may be used. The thermal process normally comprises a first thermal process to initiate a silicide reaction to the impurity region and the gate electrode, which are exposed on the semiconductor substrate; and a second thermal process to initiate crystalline phase transition to the silicide film formed by the first thermal process, and to realize low resistance. Furthermore, the first thermal process is conducted at considerably low temperature to avoid transverse growth of the silicide film via a metal film, and to form the silicide film only in a desirable region. After an unreacted metal film without occurrence of the silicide reaction during the first thermal process is removed by etching, the second thermal process is conducted at considerably high temperature. These thermal processes are conducted by using a thermal processing apparatus, such as RTP (rapid thermal process) apparatus. For example, the first thermal process can be conducted at processing temperatures of 300 to 700 degree C. for 30 to 120 seconds, and the second thermal process may be conducted under conditions at 500 to 900 degree C. of processing temperature and for 10 to 90 seconds of processing time.

Further, various technologies for forming a silicide film with lower resistance have been proposed. For example, in Japanese Patent Application Laid-Open No. H10-335261, a technology is proposed where titanium is used as the metal film and the second thermal process is conducted using a batch processing with a furnace in a pressure state higher than atmospheric pressure. With this technology, for example, the second thermal process is conducted at 70 MPa processing pressure and at 700 degree C. processing temperature for 10 minutes. According to this technology, since the second thermal process is conducted in the state where stress is applied to the silicide film, the crystalline phase transition of the silicide film is accelerated and silicide film with low resistance can be realized.

### SUMMARY OF THE INVENTION

In the case of initiating a silicide reaction, it is known that if the metal film deposited onto the semiconductor substrate for silicide film formation is oxidized, the silicide reaction is inhibited and the silicide film becomes highly resistant. Consequently, a titanium nitride or tungsten nitride film is normally formed on the metal film, as an oxidation resistant film for restraining the oxidation of metal film.

However, the present inventor has discovered that on the occasion of the first thermal process, when oxidizing gas is mixed within a processing room, even if an oxidation resistant film is formed on the metal film, the resistance value for the silicide film is increased.

FIG. 4 is a graph showing resistance values for silicide films formed where the first thermal process is conducted in a nitrogen gas atmosphere with 0%, 5%, 10% or 13% of the mixing ratio of oxygen. Furthermore, the RTP apparatus is used at the first thermal process, and the processing is accomplished at 450 degree C. for 60 seconds. Further, in FIG. 4, a cobalt film is used as a metal film for forming the silicide film, and the oxidation resistant film formed from a titanium nitride film is formed on the cobalt film.

As is understood from FIG. 4, if the first thermal process is conducted in the state where oxygen is mixed within the processing room, the resistance value for the formed silicide film is increased. Accordingly, it is understood that the oxygen mixed inside the processing room penetrates through the oxidation resistant film and reaches the cobalt film, inhibiting the silicide reaction. In other words, when an oxidation resistant film is left in atmosphere at room temperature, the oxidation of the metal film is inhibited. However, this film cannot inhibit the oxidation of the metal film during the thermal process. In addition, during the first thermal process, if oxidizing gas is mixed within the processing room, as described in Japanese Patent Application Laid-Open No. H10-335261, even though the second thermal process is conducted under high pressure and the crystalline phase transition of the cobalt silicide film is accelerated, a silicide film with lower resistance cannot be obtained, and the increased resistance value for the silicide film may decrease the electric characteristics of the semiconductor device.

In the meantime, if the first thermal process is conducted in a state where the oxidizing gas is mixed within the processing room, the titanium nitride film, which is an oxidation resistant film, may be oxidized. If the titanium nitride film is not oxidized, the titanium nitride film on the cobalt film is removed along with the cobalt film when removing the unreacted cobalt film by etching after the first thermal process. However, when the titanium nitride film is oxidized, when removing the unreacted cobalt film by etching, the oxidized titanium nitride film will not be removed. As a result, a leak path via the residual titanium nitride film is formed on the semiconductor device, with the problem of decreasing the product yield of the semiconductor device. Even if the complete leak path is not formed, there is a deterioration of the long-term reliability of the semiconductor device.

The present invention has been proposed by taking the conventional circumstances into consideration, and the objective is to provide a method for manufacturing a semiconductor device that can stably form a silicide film with low resistance.

In order to resolve the problem, the present invention has adopted the technical means mentioned below. First, the present invention assumes a method for manufacturing a semiconductor device including a silicide film. In the method for manufacturing a semiconductor device relating to the present invention, first, a metal film is formed on the substrate in the state where a silicide forming region is exposed on the surface of the substrate. Next, thermal processing is accomplished of the substrate where the metal film is formed at a pressure higher than that of atmospheric pressure, and a silicide film is formed by reacting silicon contained in the silicide forming region with the metal film. Subsequently, after removing the unreacted metal film in the thermal process, crystalline phase transition occurs due to the thermal process, and the silicide film formed on the substrate is processed to have low resistance.

In this configuration, the processing temperature for thermal processing under the pressure higher than atmosphere can be set at 600 degree C. or lower. Further, it is preferable that the processing pressure of the thermal process be 1,040 hPa or higher. Further, the oxidation resistant film may be formed onto the metal film prior to the silicide film formation step. The oxidation resistant film, for example, may be made from a titanium nitride or tungsten nitride film.

Further, for the metal film, metal containing at least one metal selected from the group consisting of cobalt, nickel and titanium can be used.

With the present invention, even if the leak path is generated within the processing room where the thermal process is conducted due to abnormality in facilities, it is possible to stably form a silicide film without being affected by oxygen in the atmosphere, preventing the characteristic deterioration of the semiconductor device and the deterioration of long-term reliability.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A to 1D are sectional views showing a manufacturing process for a semiconductor device in one embodiment of the present invention.

FIG. 2 is a block diagram of substantial parts in the thermal processing apparatus in one embodiment of the present invention.

FIG. 3 is a diagram for explaining the thermal process sequence in the thermal processing apparatus shown in FIG. 2.

FIG. 4 is a graph showing a relationship between an oxygen mixing ratio in the processing atmosphere and the resistance of silicide film.

### DETAILED DESCRIPTION OF PREFERRED EMBODIMENTS

An embodiment of the present invention is described in detail hereafter with reference to the drawings. In the embodiment below, the present invention is realized as a case example where a silicide film is formed in a semiconductor device comprising an MIS transistor having a silicide gate.

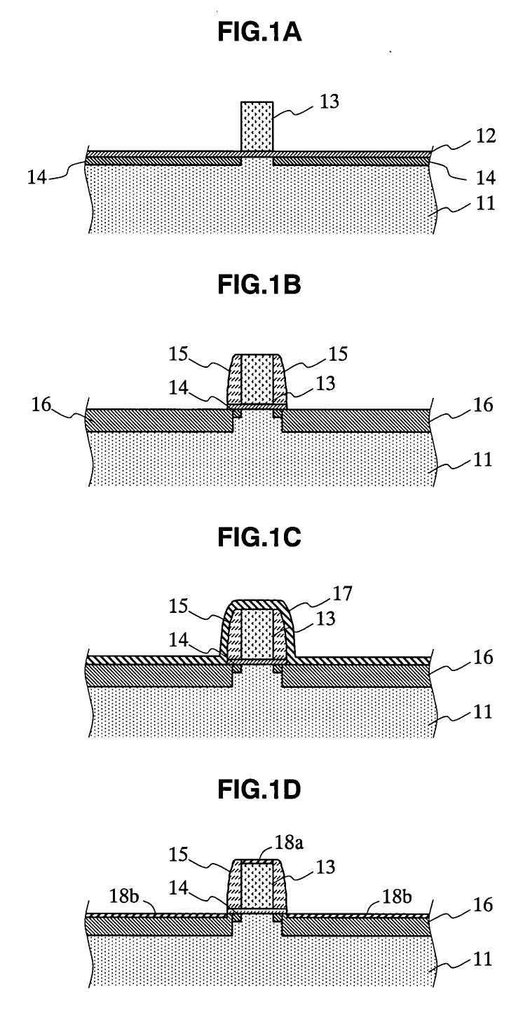

FIGS. 1A to 1D are sectional views a manufacturing process for a semiconductor device in an embodiment of the present invention. First, as shown in FIG. 1A, a gate insulating film 12, which is made from silicon oxide film with 10 nm or less of thickness, is formed in the region of a silicon substrate 11 partitioned by a trench type isolation (not shown) using a thermal oxidation method. A polycrystalline silicon film with 200 nm or less of thickness is deposited onto the gate insulating film 12 using a CVD (chemical vapor deposition) method. Application of well-known lithography technology and dry-etching technology to the polycrystalline silicon film results in the formation of a gate electrode 13 made from polycrystalline silicon on the gate insulating film 12. Subsequently, implantation of impurity ions into the silicon substrate 11 using the gate electrode 13 as a mask results in the formation of a low temperature impurity region 14.

Next, as shown in FIG. 1B, after depositing an oxidation film with approximately 100 nm of thickness onto the silicone substrate 11 using the CVD method, etching-back of the oxidation film results in the formation of an insulating sidewall 15 made from the oxidation film on the side of the gate electrode 13. Next, implantation of impurity ions into the silicon substrate 11 using the gate electrode 13 and the insulating sidewall 15 as a mask results in the formation of a high concentration impurity region 16. Here, the low concentration impurity region 14 and the high concentration impurity region 16 function as a source region and a drain region of MIS type transistor.

Subsequently, as shown in FIG. 1C, a cobalt film with approximately 10 nm of thickness, which is a metal material for forming a silicide film, is formed over the entire surface of the silicon substrate 11 using a sputtering method. A titanium nitride film with approximately 13 nm of thickness, which is an oxidation resistant film, is formed on the cobalt film. Furthermore, in FIG. 1C, a stacked film with the cobalt film and the titanium nitride film is shown as a metal film 17. Next, in the RTP apparatus, the first thermal process is conducted in the pure nitrogen gas atmosphere, where thermal processing is accomplished at 300 to 500 degree C. for approximately 20 to 120 sec. The gate electrode 13 and silicon in the high concentration impurity region 16 are reacted with a cobalt film by the thermal process, forming a silicide film (mainly CoSi). Since the cobalt film will not react with the insulating sidewall 15, the silicide film is formed only on the gate electrode 13 and the high concentration impurity region 16 in a self-aligning manner. Also, the titanium nitride film remains intact, as unreacted metal.

Next, as shown in FIG. 1D, the unreacted cobalt film and titanium nitride film remaining on the insulating sidewall 15 are removed by etching using HPM (hydrochloric acid-hydrogen peroxide-water mixture) cleaning liquid. With the etching removal, a silicide film 18a is formed on the gate electrode 13, and a silicide film 18b is formed on the high concentration impurity region 16.

Subsequently, in the RTP apparatus, the second thermal process is conducted in a pure nitrogen gas atmosphere. The second thermal process is performed at 600 to 850 degree C. for approximately 20 to 120 sec. The second thermal process initiate crystalline phase transition of the silicide film (mainly CoSi) formed via the first thermal process, and the silicide film mainly becomes a cobalt disilicide (CoSi2). As a result, the silicide film 18a on the gate electrode 13 and the silicide film 18b on the high concentration impurity region 16 come to have low resistance, respectively.

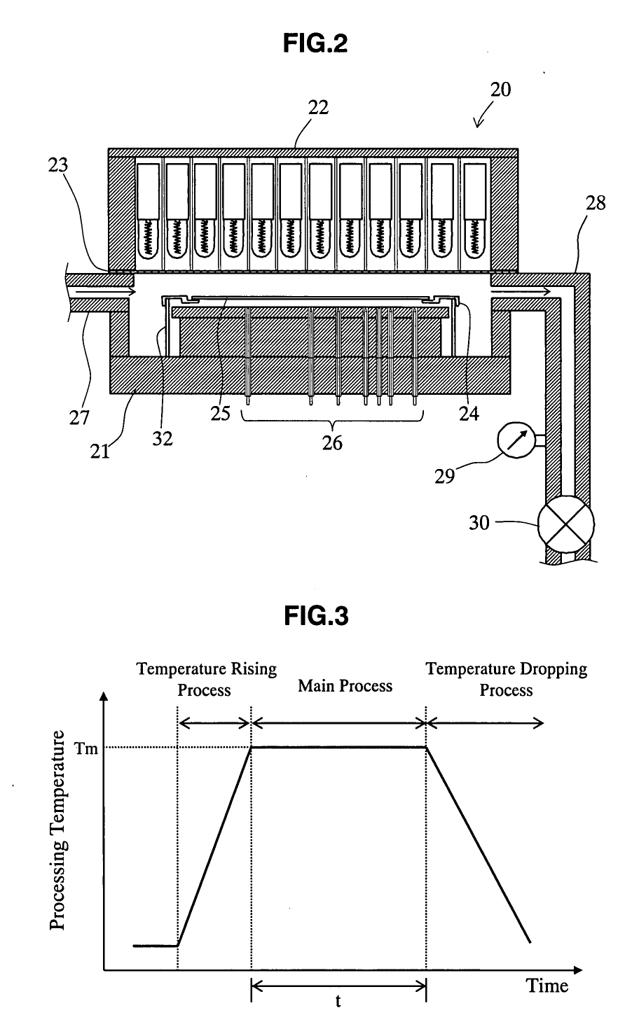

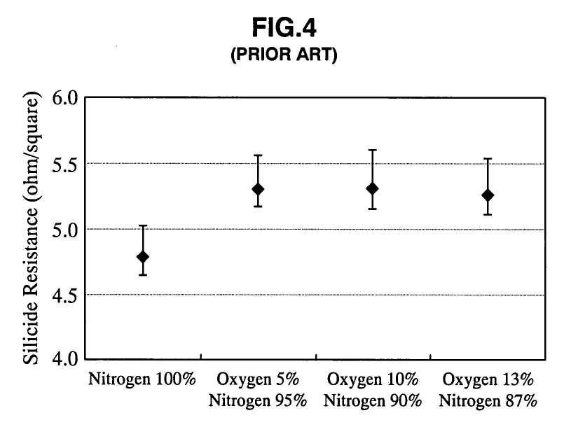

FIG. 2 shows a substantial part block diagram of the RTP apparatus to be used for the first and second thermal processes. As shown in FIG. 2, an RTP apparatus 20 is equipped with a metal chamber 21. A lamp unit 22 comprising many tungsten halogen lamps as a lamp light source, is arranged at the upper portion of the chamber 21 via a quartz plate 23. A support ring 24 to horizontally support a substrate 25 is arranged within the chamber 21. The support ring 24 is supported by a rotary cylinder 32 rotatably arranged on the bottom of the chamber 21 within the horizontal surface. The rotary cylinder 32 is rotated by a not-shown drive mechanism during the thermal process, and the substrate 25 is rotated, for example, at 90 to 250 revolutions per min.

Further, multiple temperature probes 26 are arranged on the rear surface of the substrate 25 mounted on the support ring 24 at positions from a position facing the center of the substrate 25 throughout a position facing the outer circumference. The temperature probes 26 measure the surface temperature and temperature distribution of the substrate 25 based on radiated light from the rear surface of the substrate 25. Adjustment of volume of light radiated from each lamps of the lamp unit 22 based upon the measured temperature of the substrate 25 by a not-shown temperature controller results in the maintenance of the temperature within the surface of the substrate 25 at a predetermined processing temperature. Furthermore, the chamber 21 is provided with a gas introductory path 27 to introduce processing gas to the chamber 21 and a gas leading path 28 to exhaust the processing gas within the chamber 21. The processing pressure during the thermal process is maintained at a predetermined pressure by adjusting the degree of opening in a pressure control valve 30 based on a measurement value for a pressure gauge connected to the gas leading path 28. Furthermore, the substrate 25 is loaded/unloaded, for example, through a not-shown substrate gateway provided on a sidewall of the chamber 21 and opened/closed at any time.

FIG. 3 is a diagram showing a general thermal process sequence to be used for the thermal process in the RTP apparatus 20. As shown in FIG. 3, the thermal process sequence comprises a temperature rising process, a main process to maintain thermal process temperature Tm only for predetermined time t and a temperature dropping process. Furthermore, the processing time is the predetermined time t and the processing temperature is temperature Tm.

In the present embodiment, in the case of conducting the first and second thermal processes, the degree of opening in the pressure control valve 30 is adjusted so as to adjust pressure within a space arranged the substrate 25 in the chamber 21 (processing room) at atmosphere or greater. In this case, for example, even if a leak path is generated between the chamber 21 and the outside of the chamber 21 due to a apparatus abnormality, such as a mounting abnormality of the quartz plate 23 or a mounting abnormality of the temperature probes 26, the invasion of atmosphere into the chamber 21 can be prevented. For example, if atmosphere flows into the chamber 21 at 1 SLM (standard liter per minute) via the leak path, approximately 5% of oxygen will be mixed. In other words, according to the present embodiment, the first thermal process can be steadily conducted in a state where no oxygen is mixed into atmosphere, stably forming a silicide film with low resistance.

Furthermore, the pressure at the processing room should be higher than atmospheric pressure within the clean room where the RTP apparatus 20 is arranged, and it is desirable that it be within the range of 1,040 hPa through 1,200 hPa, because if the pressure is lower than 1,040 hPa, the flow-in prevention effect of atmosphere into the chamber 21 is lowered. Further, if the pressure is higher than 1,200 hPa, even though the condition is normal where no leak path is present between the chamber 21 and the outside of the chamber 21, the processing gas within the chamber 21 may leak into the clean room from, for example, an interface with the quartz plate 23, due to the pressure within the chamber 21.

Further, in the embodiment, both the first and second thermal processes are implemented in pressured atmosphere as an especially preferred mode. However, implementation of at least the first thermal process in the pressured atmosphere enables the obtainment of the effect to inhibit the resistance increase in the silicide film.

In addition, in the first and second thermal processes, although pure nitrogen gas is introduced into the chamber 21 as processing gas, the processing gas may be any inert gas, such as argon or xenon. Further, it is desirable to use gas with 99.99% or greater of purity to be normally used in the manufacturing process for a semiconductor device as the processing gas.

In addition, in the embodiment, the case has been explained where two thermal processes are implemented in the process up to the step to realize low resistance in the silicide film after the metal film is formed. However, the number of the thermal processes does not have to be only two. For example, even when unevenness is present on the interface between the metal film and the silicide forming region exposed onto the substrate or when silicide may abnormally grow in the silicide forming region locally, the thermal process in the step to realize low resistance in the silicide film can be divided two or more times after the metal film is formed.

As described above, with the present invention, even when a leak path is generated to the processing room where the thermal process is conducted due to the apparatus abnormality, it is possible to stably form the silicide film without being affected by oxygen in atmosphere, preventing deterioration of characteristics of a semiconductor device or deterioration of long-term reliability.

The present invention is not limited to the embodiment described above, but it is variously modifiable or applicable within the scope to prove the efficacy of the present invention. For example, in the embodiment, the case is described where the present invention is applied to the RTP apparatus. Needless to say, the present invention is applicable to other thermal processing apparatuses. Further, in the embodiment, the case where the cobalt silicide film is formed is described. However, similar efficacy is obtained even where titanium or nickel is deposited in the state where the silicide film forming region is exposed on the surface of the substrate and titanium silicide or nickel silicide is formed. It is not essential that the oxidation resistant film be titanium nitride, but tungsten nitride may also be used. In addition, it is not essential to form the oxidation resistant film on the metal film, so an oxidation resistant film does not have to be formed.

The present invention provides the efficacy to stably form the silicide film, and it is useful as a method for manufacturing a semiconductor device.

1. A method for manufacturing a semiconductor device including a silicide film, comprising the steps of:
forming a metal film on a substrate in the state where a silicide forming region is exposed onto a surface of the substrate;
forming the silicide film by reacting silicon contained in the silicide forming region with the metal film via thermal process at pressure higher than atmosphere;
removing an unreacted metal film during the thermal process; and
reducing resistance of the silicide film through crystalline phase transition of the silicide film via thermal process.

2. A method for manufacturing a semiconductor device according to claim 1, wherein processing temperature of the thermal process at the pressure higher than atmosphere is 600 degree C. or lower.

3. A method for manufacturing a semiconductor device according to claim 1, wherein processing pressure of the thermal process at the pressure higher than atmosphere is 1,040 hPa or higher.

4. A method for manufacturing a semiconductor device according to claim 2, wherein processing pressure of the thermal process at the pressure higher than atmosphere is 1,040 hPa or higher.

5. A method for manufacturing a semiconductor device according to claim 1, further comprising the step of forming an oxidation resistant film onto the metal film before the silicide film forming step.

6. A method for manufacturing a semiconductor device according to claim 5, wherein the oxidation resistant film is made from titanium nitride or tungsten nitride.

7. A method for manufacturing a semiconductor device according to claim 1, wherein the metal film contains at least one metal selected from the group consisting of cobalt, nickel and titanium.

8. A method for manufacturing a semiconductor device according to claim 2, wherein the metal film contains at least one metal selected from the group consisting of cobalt, nickel and titanium.

9. A method for manufacturing a semiconductor device according to claim 1, wherein after the formation of the metal film, the thermal process up to the step where low resistance of the silicide film is realized is divided into twice or more times.
